(19) United States
(12) Patent Application Publication
(10) Pub. No.: US 2026/0050281 A1
(43) Pub. Date: Feb. 19, 2026

(54) VOLTAGE REGULATOR

(71) Applicant: SK hynix Inc., Gyeonggi-do (KR)

(72) Inventor: Chan Hui JEONG, Gyeonggi-do (KR)

(21) Appl. No.: 19/007,556

(22) Filed: Jan. 2, 2025

(30) Foreign Application Priority Data
Aug. 14, 2024 (KR) 10-2024-0109166

(51) Int. Cl. G05F 1/575

(52) U.S. Cl. CPC G05F 1/575

(57) ABSTRACT

A voltage regulator includes a voltage dividing circuit, a switch circuit and a control circuit. The voltage dividing circuit divides a voltage of a sourcing node to generate a plurality of voltages through a plurality of nodes. The switch circuit couples the sourcing node to a switch node of the plurality of nodes in response to a switch control signal. The control circuit activates the switch control signal during at least a partial period of an initialization period.

### CROSS-REFERENCES TO RELATED APPLICATION

The present application claims priority under 35 U.S.C. § 119(a) to Korean Application No. 10-2024-0109166 filed on Aug. 14, 2024, which is incorporated herein by reference in its entirety.

### BACKGROUND

### 1. Technical Field

Various embodiments of the present disclosure relate to a voltage regulator included in a semiconductor device.

### 2. Related Art

Semiconductor devices are the core components of electronic devices and have a wide range of modern applications, for example, in technologies such as computing, communications, artificial intelligence, and a memory. Semiconductor devices may include transistors, diodes, integrated circuits (ICs), and more.

Semiconductor devices may require a constant voltage to operate reliably under various operating conditions. To this end, a voltage regulator may convert an external voltage into internal voltages having various levels required by a semiconductor device. In particular, technical measures to enable the voltage regulator to quickly stabilize a level of voltage output therefrom during an initial operation of the semiconductor device have been continuously researched to optimize the performance of the semiconductor device.

### SUMMARY

In an embodiment of the present disclosure, a voltage regulator may include a voltage dividing circuit, a switch circuit, and a control circuit. The voltage dividing circuit may be configured to divide a voltage of a sourcing node to generate a plurality of voltages through a plurality of nodes. The switch circuit may be configured to couple the sourcing node to a switch node of the plurality of nodes in response to a switch control signal. The control circuit may be configured to activate the switch signal during at least a partial period of an initialization period.

In an embodiment of the present disclosure, a voltage regulator may include a voltage dividing circuit, and an output circuit. The voltage dividing circuit may be configured to divide a voltage of a sourcing node to generate a plurality of voltages through a plurality of nodes. The output circuit may be coupled to first nodes of the plurality of nodes, and may be configured to output a voltage of a node corresponding to a selection code, among the first nodes. During an initialization period, the node corresponding to the selection code may have a lowest voltage level among the first nodes.

In an embodiment of the present disclosure, a voltage regulator may include a voltage dividing circuit, an output circuit, and a selection code generation circuit. The voltage dividing circuit may be configured to divide a voltage of a sourcing node to generate a plurality of voltages through a plurality of nodes. The output circuit may be coupled to first nodes of the plurality of nodes, and may be configured to output a voltage of a node corresponding to a selection code, among the first nodes. The selection code generation circuit may be configured to output an initial code as the selection code, regardless of an input selection code, in response to an initialization period signal, and output a pattern of the input selection code as the selection code in response to an inverted initialization period signal.

### BRIEF DESCRIPTION OF THE DRAWINGS

FIG. 1 is a circuit diagram illustrating a voltage regulator according to an embodiment of the present disclosure.

FIG. 2 is a circuit diagram illustrating a current supply circuit according to an embodiment of the present disclosure.

FIG. 3 is a block diagram illustrating a control circuit according to an embodiment of the present disclosure.

FIG. 4A is a circuit diagram illustrating a first type of level shifter according to an embodiment of the present disclosure.

FIG. 4B is a circuit diagram illustrating a second type of level shifter according to an embodiment of the present disclosure.

FIG. 5 is a timing diagram of signals to illustrate an operation of a voltage regulator according to an embodiment of the present disclosure.

FIG. 6 is a timing diagram of signals to illustrate an operation of a voltage regulator according to an embodiment of the present disclosure.

### DETAILED DESCRIPTION

Hereinafter, embodiments of the present disclosure will be described in more detail with reference to the accompanying drawings.

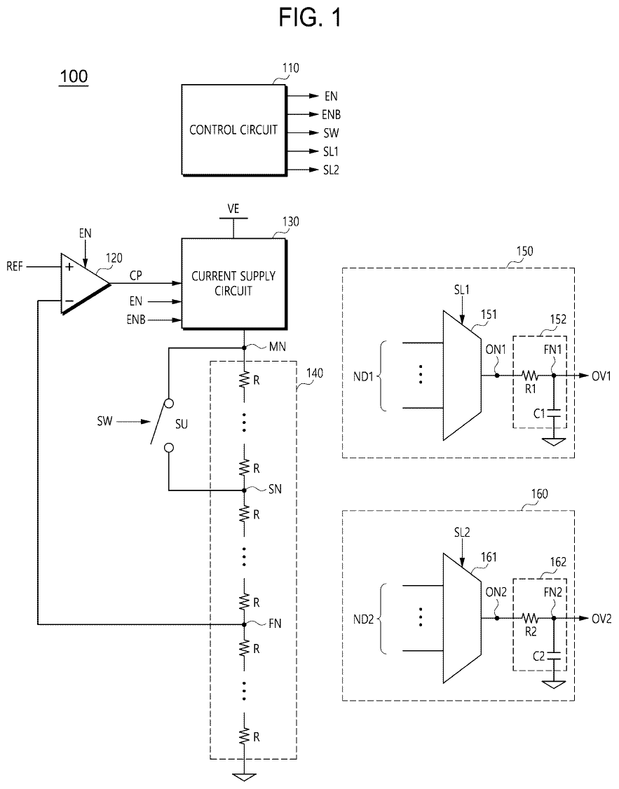

FIG. 1 is a circuit diagram illustrating a voltage regulator 100 according to an embodiment of the present disclosure.

Referring to FIG. 1, the voltage regulator 100 may include a control circuit 110, a comparison circuit 120, a current supply circuit (i.e., a current source) 130, a voltage dividing circuit 140, a first output circuit 150, a second output circuit 160, and a switch circuit SU.

The control circuit 110 may output an enable signal EN, an inverted enable signal ENB, a switch control signal SW, a first selection code SL1, and a second selection code SL2 to control an operation of the voltage regulator 100.

The enable signal EN may be a signal that is activated while the voltage regulator 100 is performing an operation. The inverted enable signal ENB may be an inverted signal of the enable signal EN. An initialization period may begin immediately after the enable signal EN is activated. The initialization period may be a period for stabilizing each of a first output voltage OV1 and a second output voltage OV2 output from the first output circuit 150 and the second output circuit 160, respectively, to a corresponding initial level.

The switch control signal SW may be a signal for controlling the turn-on of the switch circuit SU. When the enable signal EN transitions to an activated state, the switch control signal SW may also transition to an activated state. The switch control signal SW may be activated during the initialization period. The switch control signal SW may be activated during a partial period of the initialization period.

The first selection code SL1 may be a signal for controlling the first output circuit 150 to output a voltage of a node corresponding to the first selection code SL1 among first nodes ND1 coupled to the voltage dividing circuit 140 as the first output voltage OV1. During the initialization period, the control circuit 110 may generate the first selection code SL1 as a predetermined initial code. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm. After the initialization period, the control circuit 110 may generate the first selection code SL1 as a predetermined code.

The second selection code SL2 may be a signal for controlling the second output circuit 160 to output a voltage of a node corresponding to the second selection code SL2 among second nodes ND2 coupled to the voltage dividing circuit 140 as the second output voltage OV2. During the initialization period, the control circuit 110 may generate the second selection code SL2 as a predetermined initial code. After the initialization period, the control circuit 110 may generate the second selection code SL2 as a predetermined code.

The comparison circuit 120 may output a comparison signal CP by comparing a level of a reference voltage REF and a voltage level of a feedback node FN in response to the enable signal EN. For example, the comparison circuit 120 may be configured with an OP amp and may receive the reference voltage REF at a non-inverting input “+” and the voltage of the feedback node FN at an inverting input “−”. A voltage level of the comparison signal CP may be increased when the voltage level of the reference voltage REF is higher than the voltage level of the feedback node FN, and the voltage level of the comparison signal CP may be decreased when the voltage level of the feedback node FN is higher than the voltage level of the reference voltage REF.

The current supply circuit 130 may generate a voltage at a sourcing node MN between the current supply circuit 130 and the voltage dividing circuit 140 by supplying a current to the sourcing node MN in response to the enable signal EN, the inverted enable signal ENB, and the comparison signal CP. A source voltage VE may be, for example, an externally input voltage. The current supply circuit 130 may increase a voltage level of the sourcing node MN by supplying more current to the sourcing node MN when a voltage level of the comparison signal CP increases, and may decrease a voltage level of the sourcing node MN by supplying less current to the sourcing node MN when a voltage level of the comparison signal CP decreases.

The voltage dividing circuit 140 may divide a voltage of the sourcing node MN to generate a plurality of voltages at a plurality of nodes. The voltage dividing circuit 140 may include a plurality of resistors R connected in series between the sourcing node MN and a ground node. The plurality of nodes between the resistors R may include a switch node SN and a feedback node FN. The switch node SN may be closer to the sourcing node MN than the feedback node FN. The switch node SN may be positioned between the sourcing node MN and the feedback node FN, and a voltage level of the switch node SN is higher than a voltage level of the feedback node FN. At least one resistor R may be connected between the sourcing node MN and the switch node SN, at least one resistor R may be connected between the switch node SN and the feedback node FN, and at least one resistor R may be connected between the feedback node FN and the ground node.

The switch circuit SU may be coupled in parallel with the resistors R between the sourcing node MN and the switch node SN. The switch circuit SU may couple the sourcing node MN and the switch node SN by being turned on in response to the switch control signal SW. The switch circuit SU may reduce resistance and capacitance between the sourcing node MN and the switch node SN by being turned on in response to the switch control signal SW.

The first output circuit 150 may be coupled to the first nodes ND1 selected from a plurality of nodes coupled to the voltage dividing circuit 140. In response to the first selection code SL1, the first output circuit 150 may output a voltage of a node corresponding to the first selection code SL1 among the first nodes ND1 as the first output voltage OV1. The first nodes ND1 may correspond to patterns of the first selection code SL1, respectively. A node electrically closest to the ground node among the first nodes ND1 may be referred to as a first minimum voltage node. The first minimum voltage node may be a node that outputs the lowest voltage among the first nodes ND1. The first minimum voltage node may be a node located between the switch node SN and the ground node. The first minimum voltage node may correspond to a predetermined pattern of the first selection code SL1, such as a zero code. The first output circuit 150 may output a voltage of the first minimum voltage node of the first nodes ND1 as the first output voltage OV1 in response to the first selection code SL1 being a zero code.

During the initialization period, the first selection code SL1 may be generated as an initial code. When the first selection code SL1 is input as the initial code, the first output voltage OV1 may be stabilized to a predetermined initial level. In an embodiment, a node corresponding to the initial code of the first selection code SL1 among the first nodes ND1 may be a node located between the switch node SN and the ground node.

In an embodiment, the initial code of the first selection code SL1 may be a zero code. A node corresponding to the initial code of the first selection code SL1 among the first nodes ND1 may be the first minimum voltage node.

After the initialization period, the first selection code SL1 may be changed to a predetermined code corresponding to a predetermined target level of the first output voltage OV1. When the first selection code SL1 is input with the predetermined code, the first output voltage OV1 may be output with the target level.

In an embodiment, the target level of the first output voltage OV1 may be equal to or higher than the initial level of the first output voltage OV1.

The first output circuit 150 may include a first selection circuit 151 and a first filter circuit 152.

The first selection circuit 151 may be coupled to the first nodes ND1. The first selection circuit 151 may output a voltage of a node corresponding to the first selection code SL1 of the first nodes ND1 to a first output node ON1 in response to the first selection code SL1.

The first filter circuit 152 may include a resistor R1 and a capacitor C1. The resistor R1 may be connected between the first output node ON1 and a first filtering node FN1. The capacitor C1 may be connected between the first filtering node FN1 and the ground node. The first filter circuit 152 may remove noise from a voltage of the first output node ON1 and output the first output voltage OV1 to the first filtering node FN1. In an embodiment, the first filter circuit 152 may be omitted.

The second output circuit 160 may be coupled to the second nodes ND2 selected from the plurality of nodes coupled to the voltage dividing circuit 140. The second output circuit 160 may output, in response to the second selection code SL2, a voltage of a node corresponding to the second selection code SL2 among the second nodes ND2 as the second output voltage OV2. The second nodes ND2 may correspond to patterns of the second selection code SL2, respectively. A node electrically closest to the ground node among the second nodes ND2 may be referred to as a second minimum voltage node. The second minimum voltage node may be a node that outputs the lowest voltage among the second nodes ND2. The second minimum voltage node may be a node located between the switch node SN and the ground node. The second minimum voltage node may correspond to a predetermined pattern of the second selection code SL2, for example, a zero code. The second nodes ND2 may be different from the first nodes ND1.

The second output circuit 160 may include a second selection circuit 161 and a second filter circuit 162. The second filter circuit 162 may include a resistor R2 and a capacitor C2. The configuration and operation of the second output circuit 160 may be similar to that described for the first output circuit 150.

In an embodiment, the voltage regulator 100 might not include either of the first output circuit 150 or the second output circuit 160.

In an embodiment, the voltage regulator 100 may include at least one more output circuit configured similarly to the first output circuit 150 in addition to the first and second output circuits 150, 160.

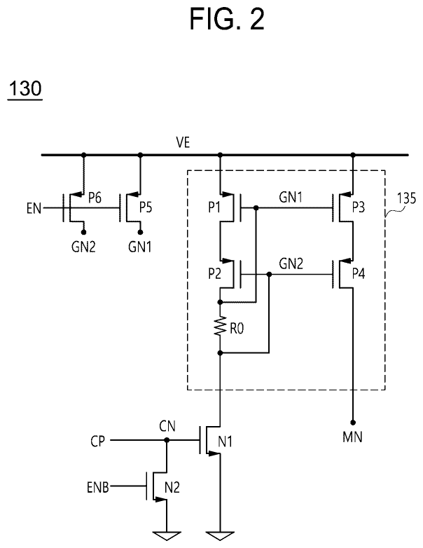

FIG. 2 is a circuit diagram illustrating the current supply circuit 130 according to an embodiment of the present disclosure.

Referring to FIG. 2, the current supply circuit 130 may include PMOS transistors P1 to P6, a resistor R0, and NMOS transistors N1, N2.

The PMOS transistor P1 may include a source connected to the source voltage VE and a gate connected to a first gate node GN1. The PMOS transistor P2 may include a source connected to a drain of the PMOS transistor P1, a drain connected to the first gate node GN1, and a gate connected to a second gate node GN2. The PMOS transistor P3 may include a source connected to the source voltage VE and a gate connected to the first gate node GN1. The PMOS transistor P4 may include a source connected to a drain of the PMOS transistor P3, a drain connected to the sourcing node MN, and a gate connected to the second gate node GN2. A resistor R0 may be connected between the first gate node GN1 and the second gate node GN2. The PMOS transistors P1 to P4 and the resistor R0 may constitute a current mirror 135.

The PMOS transistor P5 may include a source connected to the source voltage VE, a drain connected to the first gate node GN1, and a gate receiving the enable signal EN. The PMOS transistor P6 may include a source connected to the source voltage VE, a drain connected to the second gate node GN2, and a gate receiving the enable signal EN.

The NMOS transistor N1 may include a drain connected to the second gate node GN2, a source connected to the ground node, and a gate connected to a comparison node CN where the comparison signal CP is input. The NMOS transistor N2 may include a drain connected to the comparison node CN, a source connected to the ground node, and a gate receiving the inverted enable signal ENB.

When a voltage level of the comparison signal CP increases while the enable signal EN is activated to a logic high, driving force of the NMOS transistor N1 may increase. Thus, current flowing at the first gate node GN1 and the second gate node GN2 may increase, and the current flowing at the sourcing node MN by the current mirror 135 may also increase. As a result, a voltage level of the sourcing node MN may increase.

Conversely, when a voltage level of the comparison signal CP decreases while the enable signal EN is activated to a logic high, driving force of the NMOS transistor N1 may decrease. Accordingly, the current flowing at the first gate node GN1 and the second gate node GN2 may decrease, and current flowing at the sourcing node MN by the current mirror 135 may also decrease. As a result, a voltage level of the sourcing node MN may be decreased.

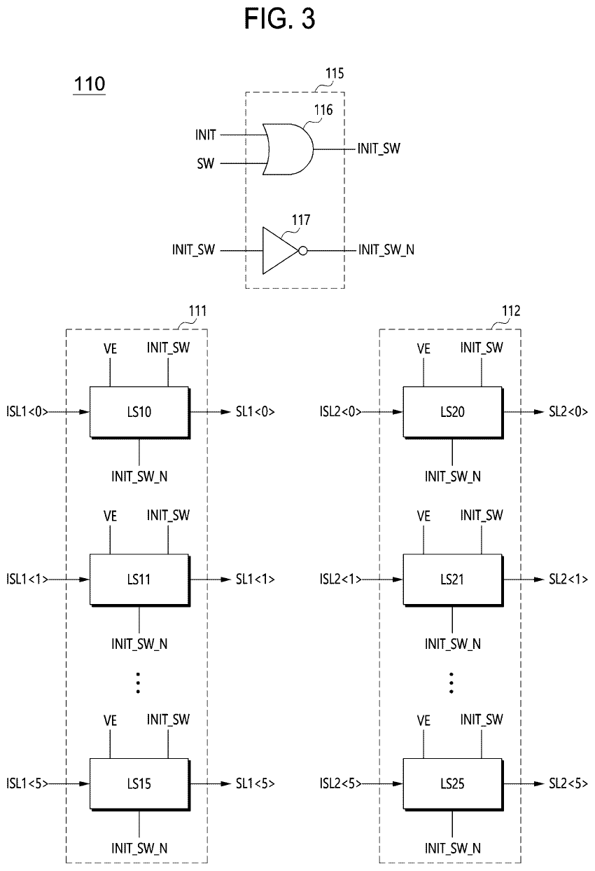

FIG. 3 is a block diagram illustrating the control circuit 110 according to an embodiment of the present disclosure.

Referring to FIG. 3, the control circuit 110 may include a signal combination circuit 115, and first and second selection code generation circuits 111, 112.

The signal combination circuit 115 may output an initialization period signal INIT_SW and an inverted initialization period signal INIT_SW_N in response to an initialization signal INIT and the switch control signal SW.

The initialization signal INIT may be a signal for controlling that the first output voltage OV1 and the second output voltage OV2 each stabilize to a corresponding initial level regardless of the operation of the switch circuit SU. When the enable signal EN transitions to an activated state, the initialization signal INIT may also transition to an activated state. The signal combination circuit 115 may output an activated initialization period signal INIT_SW while at least one of the initialization signal INIT and the switch control signal SW is activated. The signal combination circuit 115 may invert the initialization period signal INIT_SW to output the inverted initialization period signal INIT_SW_N. The initialization period may be a period during which the initialization period signal INIT_SW is activated. During the initialization period, the initialization period signal INIT_SW may be activated and the inverted initialization period signal INIT_SW_N may be deactivated. After the initialization period, the initialization period signal INIT_SW may be deactivated and the inverted initialization period signal INIT_SW_N may be activated.

The time during which the initialization signal INIT is activated and the time during which the switch control signal SW is activated may be determined based on the time it takes for each of the first output voltage OV1 and the second output voltage OV2 to stabilize to a corresponding initial level from when the voltage regulator 100 starts operating.

The signal combination circuit 115 may include an OR gate 116 and an inverter 117. The OR gate 116 may receive the initialization signal INIT and the switch control signal SW, and may perform an OR operation on the initialization signal INIT and the switch control signal SW to output the initialization period signal INIT_SW. The inverter 117 may receive the initialization period signal INIT_SW, invert the initialization period signal INIT_SW, and output the inverted initialization period signal INIT_SW_N.

The first selection code generation circuit 111 may receive the initialization period signal INIT_SW, the inverted initialization period signal INIT_SW_N, and a first input selection code ISL1, and output the first selection code SL1. The first input selection code ISL1 may be a signal for controlling the first output voltage OV1 to be output with a predetermined target level.

The first selection code generation circuit 111 may output a predetermined initial code as the first selection code SL1 while the initialization period signal INIT_SW is activated, that is, during the initialization period, regardless of the first input selection code ISL1. The initial code of the first selection code SL1 may be determined according to types of level shifters LS10 to LS15 included in the first selection code generation circuit 111, as will be described later. A voltage corresponding to a logic high level of the first selection code SL1 may be the source voltage VE.

The first selection code generation circuit 111 may output the first selection code SL1 whose logic high level is the source voltage VE by level-shifting the first input selection code ISL1 whose logic high level is a predetermined voltage while the inverted initialization period signal INIT_SW_N is activated, that is, after the initialization period. The first selection code SL1 may be generated according to a pattern of the first input selection code ISL1. The pattern of the first input selection code ISL1 may be predetermined according to a target level of the first output voltage OV1.

The first selection code generation circuit 111 may include the level shifters LS10 to LS15. The number of level shifters LS10 to LS15 may be the same as the number of bits that make up the first input selection code ISL1. Each of the level shifters LS10 to LS15 may each output an initial value constituting an initial code of the first selection code SL1 while the initialization period signal INIT_SW is activated. Each of the level shifters LS10 to LS15 may output a bit constituting the first selection code SL1 by level-shifting a corresponding bit that makes up the first input selection code ISL1, while the inverted initialization period signal INIT_SW_N is activated.

For example, the level shifter LS10 may receive the initialization period signal INIT_SW, the inverted initialization period signal INIT_SW_N, a first bit ISL1<0> of the first input selection code ISL1, and output a first bit SL1<0> of the first selection code SL1. The level shifter LS10 may output the first bit SL1<0> of the first selection code SL1 with a predetermined initial value corresponding to a type of the level shifter LS10 while the initialization period signal INIT_SW is activated. The level shifter LS10 may output the first bit SL1<0> of the first selection code SL1 by level-shifting the first bit ISL1<0> of the first input selection code ISL1 while the inverted initialization period signal INIT_SW_N is activated. The other level shifters LS11 to LS15 may operate similarly to the level shifter LS10.

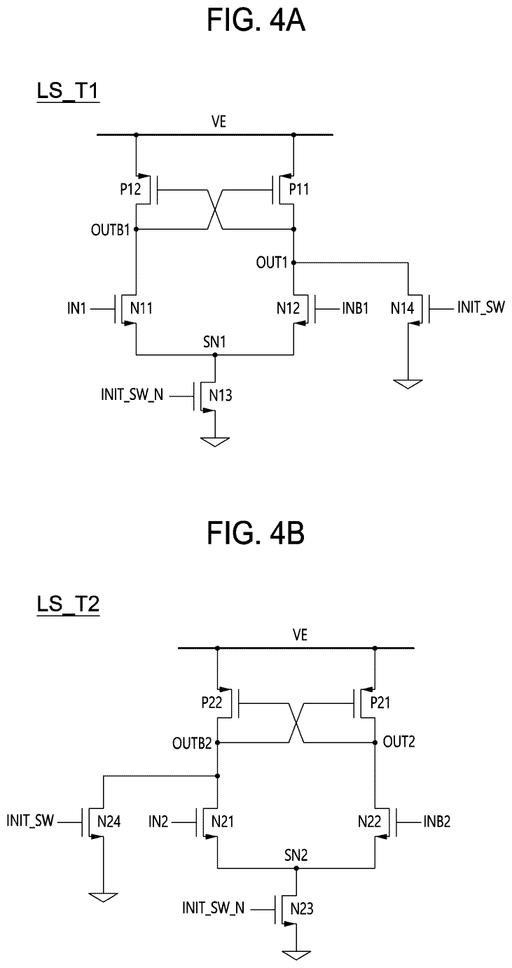

FIG. 4A is a circuit diagram illustrating a first type of level shifter LS_T1, and FIG. 4B is a circuit diagram illustrating a second type of level shifter LS_T2, according to an embodiment of the present disclosure. Each of input values input to input nodes IN1, IN2 of the level shifters LS1, LS2 may be a corresponding bit of a corresponding input selection code, and each of output values output from output nodes OUT1, OUT2 of the level shifters LS1, LS2 may be a corresponding bit of a corresponding selection code.

Referring to FIG. 4A, the first type of level shifter LS_T1 may include PMOS transistors P11, P12 and NMOS transistors N11 to N14.

The PMOS transistor P11 may include a source connected to the source voltage VE, a drain connected to the output node OUT1, and a gate connected to an inverted output node OUTB1. The PMOS transistor P12 may include a source connected to the source voltage VE, a drain connected to the inverted output node OUTB1, and a gate connected to the output node OUT1. The NMOS transistor N11 may include a drain connected to the inverted output node OUTB1, a source connected to a sink node SN1, and a gate connected to the input node IN1. The NMOS transistor N12 may include a drain connected to the output node OUT1, a source connected to the sink node SN1, and a gate connected to the inverted input node INB1. The NMOS transistor N13 may include a drain connected to the sink node SN1, a source connected to the ground node, and a gate receiving the inverted initialization period signal INIT_SW_N. The NMOS transistor N14 may include a drain connected to the output node OUT1, a source connected to the ground node, and a gate receiving the initialization period signal INIT_SW.

While the initialization period signal INIT_SW is activated, i.e., during the initialization period, an output value of the output node OUT1 may be a logic low (or, 0), regardless of an input value of the input node IN1, as the NMOS transistor N14 is turned on. While the initialization period signal INIT_SW is activated, the first type of level shifter LS_T1 may output a logic low (or, 0) as the initial value.

An input value input to the input node IN1 and an inverted input value input to the inverted input node INB1 may be in opposite phases to each other. Therefore, while the inverted initialization period signal INIT_SW_N is activated, that is, after the initialization period, an output value of the output node OUT1 of the first type of level shifter LS_T1 may be the same logical value as an input value of the input node IN1. As described above, an input value of the input node IN1 may be a predetermined voltage at a logic high level, and an output value of the output node OUT1 may be the source voltage VE at a logic high level.

Referring to FIG. 4B, the second type of level shifter LS_T2 may include PMOS transistors P21, P22 and NMOS transistors N21 to N24. The PMOS transistors P21, P22 and the NMOS transistors N21 to N23 may be configured similarly to the PMOS transistors P11, P12 and the NMOS transistors N11 to N13 of FIG. 4A. The NMOS transistor N24 may include a drain connected to an inverted output node OUTB2, a source connected to the ground node, and a gate that receives the initialization period signal INIT_SW.

While the initialization period signal INIT_SW is activated, i.e., during the initialization period, a voltage level of the inverted output node OUTB2 may decrease as the NMOS transistor N24 is turned on. Accordingly, as the PMOS transistor P21 is turned on, an output value of the output node OUT2 may be a logic high (or 1), regardless of an input value of the input node IN2. While the initialization period signal INIT_SW is activated, the second type of level shifter LS_T2 may output a logic high (or 1) as the initial value.

An input value input to the input node IN2 and an inverted input value input to the inverted input node INB2 may be in opposite phases to each other. Therefore, while the inverted initialization period signal INIT_SW_N is activated, that is, after the initialization period, an output value of the output node OUT2 of the second type of level shifter LS_T2 may be the same logical value as the input value of the input node IN2. As described above, an input value of the input node IN2 may be a predetermined voltage at a logic high level, and an output value of the output node OUT2 may be the source voltage VE at a logic high level.

Referring again to FIG. 3, the types of the level shifters LS10 to LS15 included in the first selection code generation circuit 111 may be selected from the first type and the second type, respectively. The types of the level shifters LS10 to LS15 may be determined based on which initial code should be output by the first selection code SL1 during the initialization period, regardless of the first input selection code ISL1. The types of the level shifters LS10 to LS15 may be determined according to which initial level the first output voltage OV1 should stabilize at during the initialization period. For example, during the initialization period, when the first output voltage OV1 is to be output from the first minimum voltage node of the first nodes ND1, the initial code of the first selection code SL1 may be output as ‘000000’. In this case, each of the level shifters LS10 to LS15 may be configured as the first type of level shifter LS_T1 to output 0 as the initial value.

The second selection code generation circuit 112 may receive the initialization period signal INIT_SW, the inverted initialization period signal INIT_SW_N, a second input selection code ISL2, and output a second selection code SL2. The second input selection code ISL2 may be a signal for controlling the second output voltage OV2 to be output with a predetermined target level.

The second selection code generation circuit 112 may output a predetermined initial code as the second selection code SL2 while the initialization period signal INIT_SW is activated, that is, during the initialization period, regardless of the second input selection code ISL2. The initial code of the second selection code SL2 may be determined according to the types of the level shifters LS20 to LS25 included in the second selection code generation circuit 112. A logic high level of the second selection code SL2 may be the source voltage VE.

The second selection code generation circuit 112 may output the second selection code SL2 whose logic high level is the source voltage VE by level-shifting the second input selection code ISL2 whose logic high level is a predetermined voltage while the inverted initialization period signal INIT_SW_N is activated, i.e., after the initialization period. The second selection code SL2 may be generated according to a pattern of the second input selection code ISL2. The pattern of the second input selection code ISL2 may be predetermined according to a target level of the second output voltage OV2.

The second selection code generation circuit 112 may include level shifters LS20 to LS25. The number of level shifters LS20 to LS25 may be the same as the number of bits that make up the second input selection code ISL2. Each of the level shifters LS20 to LS25 may each output an initial value constituting an initial code of the second selection code SL2 while the initialization period signal INIT_SW is activated. Each of the level shifters LS20 to LS25 may output a bit constituting the second selection code SL2 by level-shifting a corresponding bit that makes up the second input selection code ISL2, while the inverted initialization period signal INIT_SW_N is activated.

The types of the level shifters LS20 to LS25 may be selected from the first type and the second type, respectively. The types of the level shifters LS20 to LS25 may be determined based on which initial code should be output by the second selection code SL2 during the initialization period, regardless of the second input selection code ISL2. The types of the level shifters LS20 to LS25 may be determined according to which initial level the second output voltage OV2 should stabilize at during the initialization period. For example, when the initial code of the second output voltage OV2 is required to be ‘111110’, the level shifter LS20 may be configured as the first type of level shifter LS_T1 to output 0 as the initial code, and each of the level shifters LS21 to LS25 may be configured as the second type of level shifter LS_T2 to output 1 as the initial value.

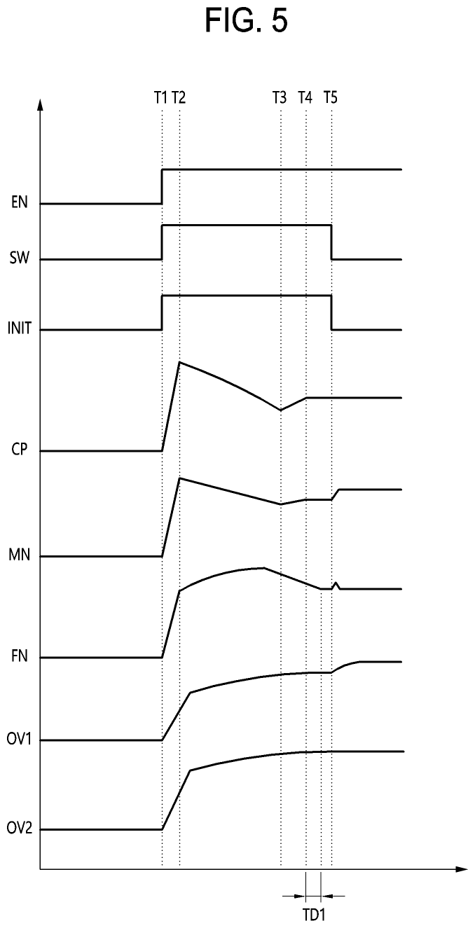

FIG. 5 is a timing diagram of signals to illustrate an operation of the voltage regulator 100 according to an embodiment of the present disclosure.

Referring to FIG. 5, at a time point T1, the enable signal EN, the switch control signal SW, and the initialization signal INIT may be activated. An initialization period may be a period between the time point T1 during which at least one of the switch control signal SW and the initialization signal INIT is activated and a time point T5.

Between the time point T1 and a time point T2, the comparison signal CP may be output from the comparison circuit 120 in response to the enable signal EN. Specifically, because a voltage level of the reference voltage REF is higher than a voltage level of the feedback node FN, a voltage level of the comparison signal CP may be increased. As the voltage level of the comparison signal CP increases, current output from the current supply circuit 130 to the sourcing node MN may increase. Thus, voltage levels of the plurality of nodes of the voltage dividing circuit 140, including the sourcing node MN and the feedback node FN, may increase.

In accordance with the embodiment described above, an initial code of the first selection code SL1 may be ‘000000’ and an initial code of the second selection code SL2 may be ‘111110’. In response to the first selection code SL1 of ‘000000’, the first output circuit 150 may output a voltage of the first minimum voltage node of the first nodes ND1 as the first output voltage OV1. Further, the second output circuit 160 may output a voltage of a node corresponding to the second selection code SL2 of ‘111110’ among the second nodes ND2 as the second output voltage OV2 in response to the second selection code SL2 of ‘111110’. The node corresponding to the second selection code SL2 of ‘111110’ may be a node between the switch node SN and the feedback node FN among the second nodes ND2.

Between the time point T2 and a time point T3, a voltage level of the feedback node FN may become higher than a voltage level of the reference voltage REF, causing a voltage level of the comparison signal CP to decrease. As the voltage level of the comparison signal CP decreases, current output from the current supply circuit 130 to the sourcing node MN may decrease. Thus, a voltage level of the sourcing node MN may decrease. Despite the decrease in the voltage level of the sourcing node MN, the voltage level of the feedback node FN may increase and then decrease more slowly than before the time point T2 due to RC delay between the sourcing node MN and the feedback node FN. When the voltage level of the sourcing node MN decreases, the voltage levels of the first output voltage OV1 and the second output voltage OV2 may increase more slowly than before the time point T2 due to the RC delay.

Between time point T3 and a time point T4, a level of the reference voltage REF may become higher than a voltage level of the feedback node FN, causing a voltage level of the comparison signal CP to increase. As the voltage level of the comparison signal CP increases, current output from the current supply circuit 130 to the sourcing node MN may increase. Thus, a voltage level of the sourcing node MN may increase. Despite the increase in the voltage level of the sourcing node MN, the voltage level of the feedback node FN may continue to decrease due to the RC delay between the sourcing node MN and the feedback node FN. The voltage levels of the first output voltage OV1 and the second output voltage OV2 may continue to increase slowly as the RC delays of the first filter circuit 152 and the second filter circuit 162 are also added.

Between time point T4 and a time point T5, a voltage level of the comparison signal CP may stabilize as a voltage level of the feedback node FN becomes equal to a voltage level of the reference voltage REF. In response to the comparison signal CP, a voltage level of the sourcing node MN may also be stabilized. Although the voltage levels of the comparison signal CP and the sourcing node MN are stabilized, the voltage levels of the feedback node FN, the first output voltage OV1, and the second output voltage OV2 may be fully stabilized after a delay time TD1 due to RC delay between the sourcing node MN and the feedback node FN. The delay time TD1 may be the time from when the comparison signal CP is stabilized to when the respective output voltages are stabilized.

At the time point T5, the switch control signal SW and the initialization signal INIT may be deactivated.

After the time point T5, when the switch circuit SU is turned off in response to the switch control signal SW, the resistance and capacitance between the sourcing node MN and the switch node SN may increase. Therefore, a voltage level of the sourcing node MN may increase slightly and then stabilize. When the switch circuit SU is turned off, the capacitance between the feedback node FN and the ground node is constant, so a voltage level at the feedback node FN may fluctuate temporarily or be constant as shown.

After the time point T5, the first selection code SL1 may be generated in response to the first input selection code ISL1, because the initialization period has ended. In response to the first selection code SL1, the first output circuit 150 may output a voltage of a node corresponding to the first selection code SL1 among the first nodes ND1 as the first output voltage OV1. A target level of the first output voltage OV1 after the time point T5 may be higher than an initial level of the first output voltage OV1. Thus, immediately after the time point T5, the first output voltage OV1 may increase slightly and then stabilize at the target level.

Similarly, the second selection code SL2 may be generated in response to the second input selection code ISL2. For example, after the time point T5, a pattern of the second input selection code ISL2 may be the same as the initial code ‘111110’ of the second selection code SL2. A target level of the second output voltage OV2 may be the same as an initial level of the second output voltage OV2. Thus, a voltage level of the second output voltage OV2 may continue to be stable immediately after the time point T5.

In summary, if the resistance and capacitance between the feedback node FN and the comparison node CN from which the comparison signal CP is output during the initialization period is large, overshoot may occur at the nodes higher than the feedback node FN due to RC delay. An overshoot at the sourcing node MN may reduce the voltage level difference between the drain and the source of each of the PMOS transistors P3 and P4, thereby reducing driving force of the PMOS transistors P3 and P4, and consequently, the stabilization of the first output voltage OV1 and the second output voltage OV2 may be delayed. However, according to embodiments of the present disclosure, the resistance and capacitance between the sourcing node MN and the switch node SN may be reduced by turning on the switch circuit SU during the initialization period, and thus the RC delay may be reduced. As a result, the overshoot during the initialization period may be suppressed, and the first output voltage OV1 and the second output voltage OV2 may stabilize more quickly.

Furthermore, even if the first output voltage OV1 is set to be output from a node located between the sourcing node MN and the switch node SN among the first nodes ND1 after the initialization period, the first output voltage OV1 during the initialization period may be output from the first minimum voltage node whose RC delay is reduced by the turn-on of the switch circuit SU. Thus, the first output voltage OV1 may stabilize to an initial level more quickly and then be adjusted to a target level.

Further, even if an initial level is required to be equal to a target level, such as the second output voltage OV2, the second output voltage OV2 may be set to be output from a node between the switch node SN and the ground node among the second nodes ND2. Thus, the second output voltage OV2 may be output from a node with reduced RC delay due to the turn-on of the switch circuit SU, and may therefore stabilize to an initial level more quickly.

In an embodiment, the switch control signal SW and the initialization signal INIT may be activated at different timings and deactivated at different timings.

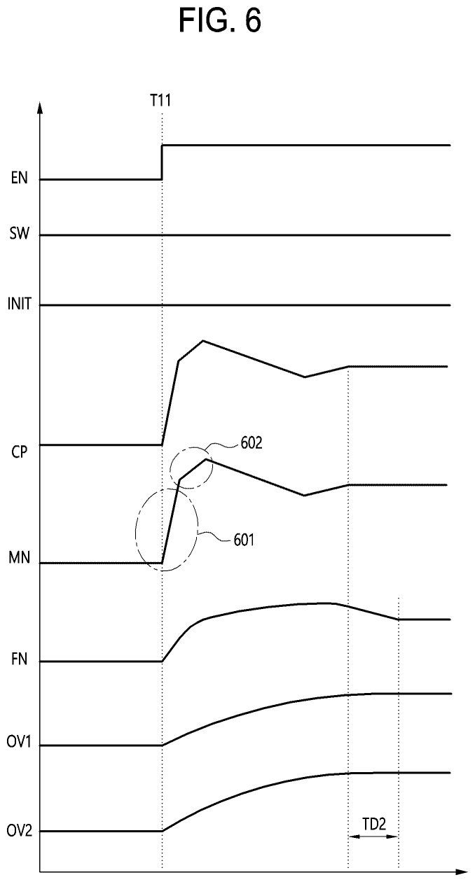

FIG. 6 is a timing diagram of signals to illustrate an operation of the voltage regulator 100 according to an embodiment of the present disclosure.

Referring to FIG. 6, after a time point T11, while the enable signal EN is activated, the switch control signal SW and the initialization signal INIT may be deactivated. When the switch circuit SU is turned off in response to the switch control signal SW, the resistance and capacitance between the feedback node FN and the comparison node CN from which the comparison signal CP is output may be large. Therefore, overshoot may occur at nodes higher than the feedback node FN due to the RC delay. In this case, an overshoot 601 generated at the sourcing node MN may reduce the voltage level difference between the drain and the source of each of the PMOS transistors P3 and P4, thereby reducing driving force of the PMOS transistors P3 and P4. Thus, the increase in the voltage level of the sourcing node MN may be suppressed (see ‘602’), and consequently, the stabilization of the first output voltage OV1 and the second output voltage OV2 may be delayed. Furthermore, because the RC delay is large, the time from when the comparison signal CP is stabilized to when the first output voltage OV1 and the second output voltage OV2 are stabilized, i.e., a delay time TD2, may be longer than the delay time TD1.

According to embodiments of the present technology, a voltage regulator can reduce RC delay, allowing an output voltage to stabilize quickly to an initial level.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure. Furthermore, the embodiments may be combined to form additional embodiments.

What is claimed is:

1. A voltage regulator comprising:
a voltage dividing circuit configured to divide a voltage of a sourcing node to generate a plurality of voltages through a plurality of nodes;
a switch circuit configured to couple the sourcing node to a switch node of the plurality of nodes in response to a switch control signal; and
a control circuit configured to activate the switch control signal during at least a partial period of an initialization period.

2. The voltage regulator of claim 1, further comprising a comparison circuit configured to compare a voltage level of a feedback node of the plurality of nodes with a level of a reference voltage to output a comparison signal.

3. The voltage regulator of claim 2, wherein a voltage level of the switch node is higher than the voltage level of the feedback node.

4. The voltage regulator of claim 2, further comprising a current supply circuit configured to supply a current to the sourcing node in response to the comparison signal to generate the voltage of the sourcing node.

5. The voltage regulator of claim 1, further comprising an output circuit coupled to first nodes of the plurality of nodes and configured to output, as an output voltage, a voltage of a node corresponding to a selection code, among the first nodes.

6. The voltage regulator of claim 5, wherein the control circuit includes a selection code generation circuit configured to:
output, during the initialization period, an initial code as the selection code, regardless of an input selection code, in response to an initialization period signal; and
output, after the initialization period, a pattern of the input selection code as the selection code in response to an inverted initialization period signal.

7. The voltage regulator of claim 6, wherein a voltage level of a node corresponding to the initial code, among the first nodes is lower than a voltage level of the switch node.

8. The voltage regulator of claim 6, wherein a node corresponding to the initial code has a lowest voltage level among the first nodes.

9. The voltage regulator of claim 6, wherein the selection code generation circuit includes level shifters configured to output initial values constituting the initial code in response to the initialization period signal, each of the initial values being determined by a type of a corresponding level shifter.

10. The voltage regulator of claim 9, wherein the level shifters are configured to respectively level-shift bits constituting the input selection code in response to the inverted initialization period signal.

11. A voltage regulator comprising:
a voltage dividing circuit configured to divide a voltage of a sourcing node to generate a plurality of voltages through a plurality of nodes; and
an output circuit coupled to first nodes of the plurality of nodes, and configured to output a voltage of a node corresponding to a selection code, among the first nodes,
wherein during an initialization period, the node corresponding to the selection code has a lowest voltage level among the first nodes.

12. The voltage regulator of claim 11, further comprising a switch circuit configured to couple the sourcing node to a switch node of the plurality of nodes in response to a switch control signal.

13. The voltage regulator of claim 12, wherein the switch control signal is activated during at least a partial period of the initialization period.

14. The voltage regulator of claim 12, further comprising a comparison circuit configured to compare a voltage level of a feedback node of the plurality of nodes with a level of a reference voltage to output a comparison signal.

15. The voltage regulator of claim 14, wherein a voltage level of the switch node is higher than the voltage level of the feedback node.

16. The voltage regulator of claim 11, further comprising a selection code generation circuit configured to:
output, during the initialization period, an initial code as the selection code, regardless of an input selection code; and
output, after the initialization period, a pattern of the input selection code as the selection code.

17. A voltage regulator comprising:
a voltage dividing circuit configured to divide a voltage of a sourcing node to generate a plurality of voltages through a plurality of nodes;
an output circuit coupled to first nodes of the plurality of nodes, and configured to output a voltage of a node corresponding to a selection code, among the first nodes; and
a selection code generation circuit configured to output an initial code as the selection code, regardless of an input selection code, in response to an initialization period signal, and output a pattern of the input selection code as the selection code in response to an inverted initialization period signal.

18. The voltage regulator of claim 17, further comprising a switch circuit configured to couple the sourcing node to a switch node of the plurality of nodes in response to a switch control signal.

19. The voltage regulator of claim 18, further comprising a signal combination circuit configured to activate the initialization period signal while at least one of the switch control signal and an initialization signal is activated.

20. The voltage regulator of claim 18, further comprising a comparison circuit configured to compare a voltage level of a feedback node of the plurality of nodes with a level of a reference voltage to output a comparison signal.

21. The voltage regulator of claim 20, wherein a voltage level of the switch node is higher than the voltage level of the feedback node.
